(19) United States
(12) Patent Application Publication
(10) Pub. No.: US 2007/0238304 A1
(43) Pub. Date: Oct. 11, 2007

(54) METHOD OF ETCHING PASSIVATION LAYER

(76) Inventor: Jui-Hung Wu, Yun-Lin Hsien (TW)

Correspondence Address: NORTH AMERICA INTELLECTUAL PROPERTY CORPORATION, P.O. BOX 506, MERRIFIELD, VA, 22116, US

(21) Appl. No.: 11/279,255

(22) Filed: Apr. 11, 2006

(51) Int. Cl. H01L 21/465

(52) U.S. Cl. 438/710; 438/738

(57) ABSTRACT

A method of etching passivation layer having an anti-reflection layer and an insulating layer subsequently disposed on a pad layer of a wafer. The method includes performing an etching process to etch the anti-reflection layer and the insulating layer. The etching process has a first-step etching performed under a first pressure and a second-step etching performed under a second pressure smaller than the first pressure. The second-step etching has an etching selectivity ratio of the anti-reflection layer to the insulating layer higher than that of the first-step etching.

### BACKGROUND OF THE INVENTION

1. Field of the Invention

The present invention relates to a method of etching a passivation layer including an anti-reflection layer and an insulating layer. More particularly, the present invention relates to a method of etching a passivation layer that controls the etching selectivity ratio of the anti-reflection layer to the insulating layer by adjusting pressure parameter of an etching process.

2. Description of the Prior Art

In integrated circuit (IC) fabrications, millions of semiconductor devices, such as transistors, are first formed on a wafer, and metal interconnection process is then performed to form interconnection layers composed of metal layers and inter-metal dielectrics. These interconnection layers electrically connect nodes of the semiconductor devices, e.g. gate and source/drain, to pad layers that serve as I/O terminals disposed above the topmost interconnection layer. Normally, the pad layer is covered with a passivation layer, and therefore the passivation layer needs to be etched to expose the pad layer.

With reference to FIG. 1 and FIG. 2, FIG. 1 and FIG. 2 are schematic diagrams illustrating a conventional method of etching a passivation layer. As shown in FIG. 1, a wafer 10 is provided. The wafer 10 includes formed semiconductor devices (not shown), an inter-metal dielectric layer 12 disposed on the semiconductor devices, a plurality of interconnection layers (only a topmost interconnection layer 14 is shown) in the inter-metal dielectric layer 12, and a dielectric thin film 16 which exposes the topmost interconnection layer 14 disposed on the inter-metal dielectric layer 12.

The dielectric thin film 14 is covered with a silicon oxide dielectric layer 18 having a via hole that exposes the topmost interconnection layer 14. The sidewall of the via hole is covered with a barrier layer 20, and the barrier layer 20 is covered with a pad layer 22. A passivation layer consisting of a titanium nitride layer 24, a silicon oxide layer 26 and a silicon nitride layer 28 disposes on the pad layer 22. The titanium nitride layer 24 is used as an anti-reflection layer in a successive lithography process. The silicon oxide layer 26 and the silicon nitride layer 28 also cover the silicon oxide dielectric layer 18.

In addition, the inter-metal dielectric layer 12 further includes a fuse structure 30 formed simultaneously with the topmost interconnection layer 14. The passivation layer disposed above the fuse structure 30 has to be removed along with the step of exposing the pad layer 22. In such a case, circuit can be modified if some semiconductor devices are found invalid in an electrical test. It is appreciated that the silicon nitride layer 28 and the silicon oxide layer 26 must be etched through, while the silicon oxide dielectric layer 18 cannot be etched through. In practice, a certain thickness e.g. 1.5 kilo angstroms must be retained to protect the fuse structure 30 from being damaged in a clean process after the etching process.

As shown in FIG. 2, an etching process is performed to etch the silicon nitride layer 28 above the pad layer 22 and the fuse structure 30. Subsequently, another etching process is performed to etch the silicon oxide layer 26 and the titanium nitride layer 24 on the pad layer 22, and to etch the silicon oxide layer 26 and the silicon oxide dielectric layer 18 above the fuse structure 30 as well. It is appreciated that the conventional method uses a plasma etching process, which is carried out under a pressure of 200 mtorr or even higher. Under this high pressure, the etching selectivity ratio of titanium nitride to silicon oxide is smaller. Therefore, when the silicon oxide layer 26 above the pad layer 22 and the fuse structure 30 is etched through, plasma will still etch the titanium nitride layer 24 on the pad layer 22 and the silicon oxide dielectric layer 18 above the fuse structure 30. Since the etching selectivity ratio of titanium nitride to silicon oxide is smaller, the silicon oxide dielectric layer 18 above the fuse structure 30 will be over-etched. This over-etching may result in damages to the fuse structure 30 in successive processes.

### SUMMARY OF THE INVENTION

It is therefore one object of the claimed invention to provide a method of etching passivation layer to adjust etching selectivity.

According to the claimed invention, a method of etching passivation layer is provided. First, a wafer having a passivation layer is provided. The passivation layer includes an anti-reflection layer and an insulating layer subsequently stacked above the wafer. Subsequently, an etching process is performed to etch the anti-reflection layer and the insulating layer. The etching selectivity ratio of the anti-reflection layer to the insulating layer of the etching process is greater than 0.029.

According to the claimed invention, another method of etching passivation layer is provided. First, a wafer having a passivation layer is provided. The passivation layer includes an anti-reflection layer and an insulating layer subsequently stacked above the wafer. Subsequently, an etching process is performed to etch the anti-reflection layer and the insulating layer. The etching process includes a first-step etching performed under a first pressure and a second-step etching performed under a second pressure smaller than the first pressure. The etching selectivity ratio of the anti-reflection layer to the insulating layer of the second-step etching is greater than the etching selectivity ratio of the anti-reflection layer to the insulating layer of the first-step etching.

According to the claimed invention, still another method of etching passivation layer is provided. First, a wafer comprising a passivation layer is provided. The passivation layer includes a titanium nitride layer and a first silicon oxide layer stacked on the wafer. The wafer further includes a pad layer and a second silicon oxide layer. The titanium nitride layer is disposed on the pad layer and the first silicon oxide layer is disposed on the titanium nitride layer and the second silicon oxide layer. Subsequently, an etching process is performed to etch the titanium nitride layer and the first silicon oxide layer to expose the pad layer, and to etch the second silicon oxide layer to form a fuse structure. The etching process includes a first-step etching performed under a first pressure and a second-step etching performed under a second pressure smaller than the first pressure. The etching selectivity ratio of titanium nitride to silicon oxide of the second-step etching is greater than the etching selectivity ratio of titanium nitride to silicon oxide of the first-step etching.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 2 are schematic diagrams illustrating a conventional method of etching a passivation layer.

FIG. 3 to FIG. 6 are schematic diagrams illustrating a method of etching a passivation layer in accordance with a preferred embodiment of the present invention.

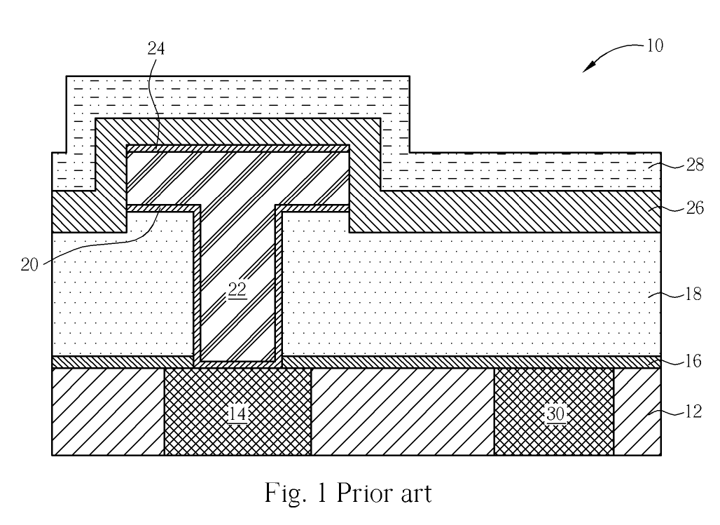

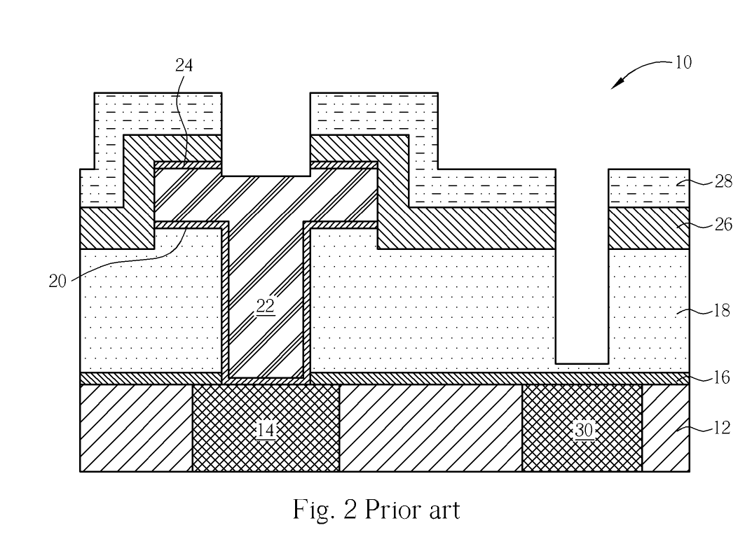

### DETAILED DESCRIPTION

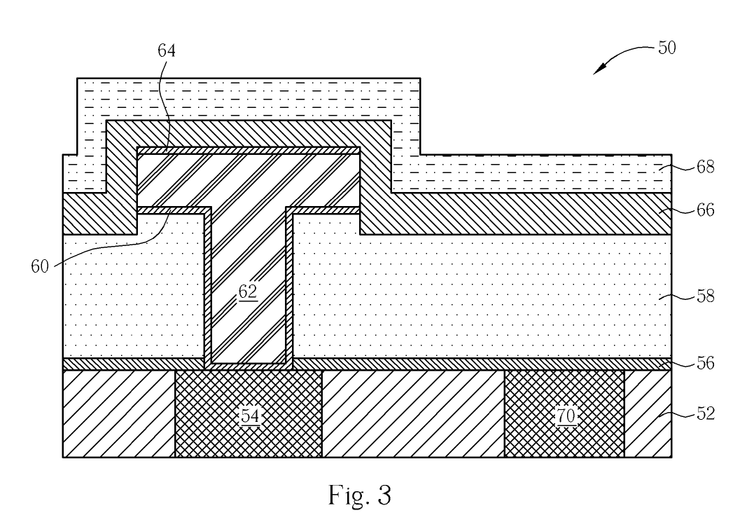

Referring to FIG. 3 to FIG. 6, FIG. 3 to FIG. 6 are schematic diagrams illustrating a method of etching a passivation layer in accordance with a preferred embodiment of the present invention. This embodiment uses a method of etching a passivation disposed above a pad layer and a fuse structure as an example, but the application of the present invention is not limited. As shown in FIG. 3, a wafer 50 e.g. a semiconductor wafer is provided. The wafer 50 includes formed semiconductor devices (not shown), an inter-metal dielectric layer 52, e.g. a silicon oxide layer, disposed on the semiconductor devices, a plurality of interconnection layers (only a topmost interconnection layer 54 is shown) formed in the inter-metal dielectric layer 52, and a dielectric thin film 56, such as a silicon nitride thin film, having a thickness of approximately 700 angstroms covering the inter-metal dielectric layer 52 and exposing the topmost interconnection layer 54.

The dielectric thin film 56 is covered with a second silicon oxide layer 58, such as a silicon oxide layer formed by CVD, having a thickness of approximately 12 kilo angstroms. The second silicon oxide layer 58 has a via hole exposing the topmost interconnection layer 54. The sidewall of the via hole is covered with a barrier layer 60 e.g. a titanium/titanium nitride thin film. The barrier layer 60 is covered with a pad layer 62 e.g. an aluminum pad layer. A passivation layer including a titanium nitride layer 64, a first silicon oxide layer 66 and a silicon nitride layer 68 is positioned atop the pad layer 62. The titanium nitride layer 64, which has a thickness of approximately 300 angstroms, is disposed on the pad layer 62, and the titanium nitride layer 64 serves as an anti-reflection layer in a successive lithography process. The first silicon oxide layer 66 can be formed by any suitable techniques. For example, the first silicon oxide layer 66 may be PSG having a thickness of approximately 4 kilo angstroms disposed on the titanium nitride layer 64 and the second silicon oxide layer 58. The silicon nitride layer 68 may have a thickness of approximately 5 kilo angstroms, and covers the first silicon oxide layer 66. In addition, the inter-metal dielectric layer 52 includes a fuse structure 70.

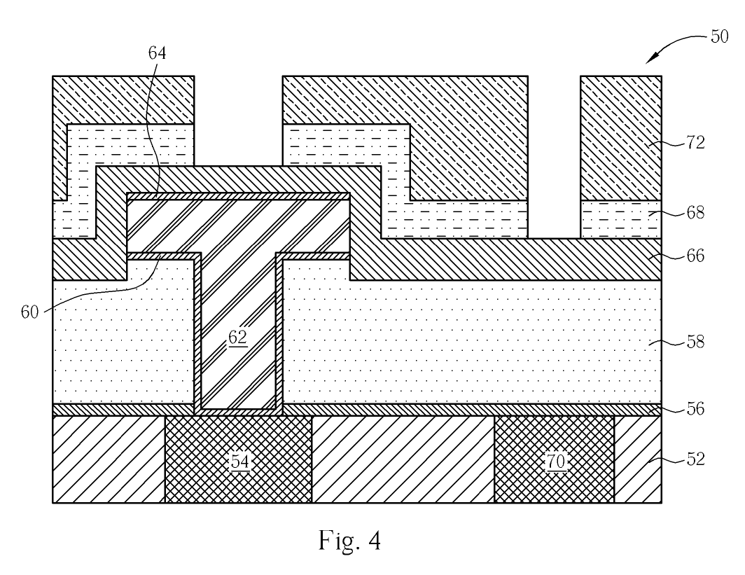

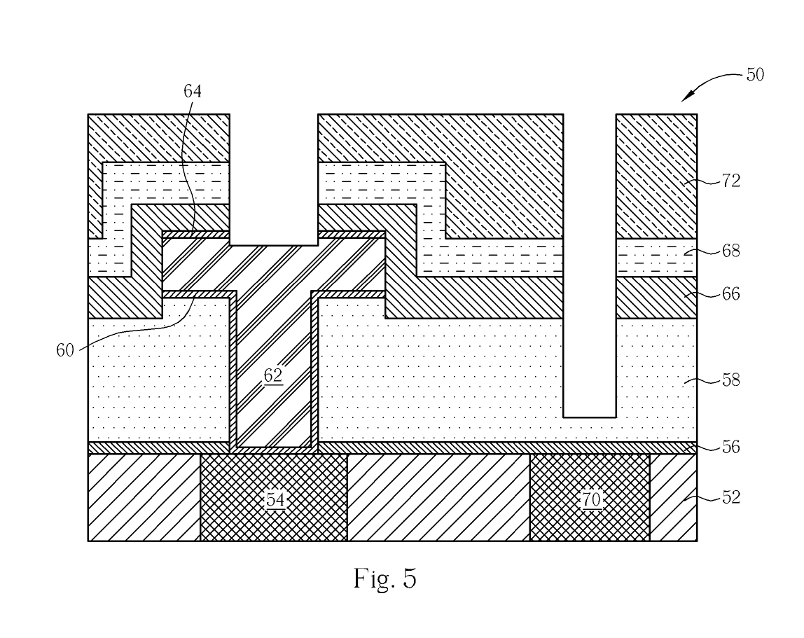

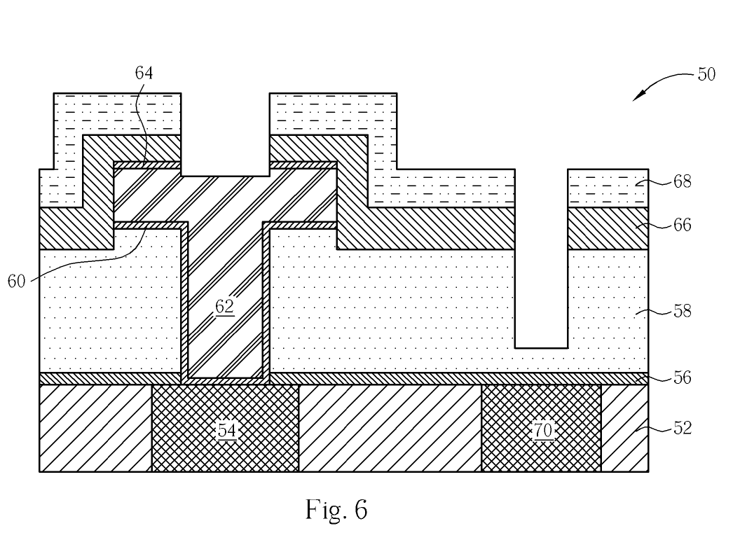

As shown in FIG. 4, a lithography process is performed to form a mask pattern 72 on the surface of the silicon nitride layer 68, and an etching process is then carried out to remove the silicon nitride layer 68 disposed above the pad layer 62 and the fuse structure 70. As shown in FIG. 5, the mask pattern 72 is used as a hard mask to perform another etching process to remove the first silicon oxide layer 66 and the titanium nitride layer 64 above the pad layer 62, and also to etch the first silicon oxide layer 66 and the second silicon oxide layer 58 above the fuse structure 70. It is appreciated that a two-step plasma etching process is selected to etch the first silicon oxide layer 66, the second silicon oxide layer 58 and the titanium nitride layer 64 in this embodiment. The plasma etching process uses CF4, SF6, CH3F, NF3 or other fluoride to etch silicon oxide and titanium nitride. The plasma etching process includes a first-step etching and a second-step etching. The first-step etching is mainly used to remove the first silicon oxide layer 66 above both the pad layer 62 and the fuse structure 70. The pressure parameter of the first-step etching is set from 180 to 220 mtorr (preferably 200 mtorr), because under this pressure fluoride plasma has a lower etching selectivity ratio of titanium nitride to silicon oxide. In other words, silicon oxide is etched more quickly. The second-step etching is mainly used to etch the titanium nitride layer 64 disposed above the pad layer 62, and the pressure parameter is set from 80 to 120 mtorr (preferably 100 mtorr). Under this pressure, fluoride plasma has a higher etching selectivity ratio of titanium nitride to silicon oxide. In other words, titanium nitride is etched more quickly and silicon oxide is etched more slowly when pressure is reduced. Consequently, the second silicon oxide layer 58 disposed above the fuse structure 70 is not over-etched, and this prevents the fuse structure 70 from being damaged in a successive clean process. As shown in FIG. 6, the mask pattern 72 is removed, and clean, segment and package processes can be successively performed.

With reference to Table 1, Table 1 illustrates an etching rate vs. pressure relation chart.

TABLE 1

| | | | Titanium |
|---|---|---|---|
| | | | nitride/silicon oxide |
| | Silicon oxide | Titanium nitride | etching selectivity |
| Pressure | etching rate | etching rate | ratio |
| 200 mtorr | 5075 | 76.8 | 0.015 |
| 100 mtorr | 3896 | 114 | 0.029 |

As listed in Table 1, when the pressure of the plasma etching process is 200 mtorr, the etching rate of silicon oxide is 5075, and the etching rate of titanium nitride is 76.8. Accordingly, the etching selectivity ratio of titanium nitride/silicon oxide is 0.015. When the pressure of the plasma etching process is reduced to 100 mtorr, the etching rate of silicon oxide is 3896, and the etching rate of titanium nitride is 114. Accordingly, the etching selectivity ratio of titanium nitride/silicon oxide increases to 0.029. It can be seen that changing the pressure parameter of the plasma etching process can effectively control the etching selectivity ratio of titanium nitride to silicon oxide. In this embodiment, the titanium nitride/silicon oxide etching selectivity ratio is maintained to 0.029 or even higher by virtue of reducing the pressure parameter. Consequently, over-etching of the second silicon oxide layer above the fuse structure is prevented. It is appreciated that the method of etching a passivation layer is not limited to etch titanium nitride and silicon oxide, and can be applied to etch other composite passivation layer. For example, the silicon oxide layer can be other insulating layer, and the titanium nitride layer can be other anti-reflection layer. In addition, the passivation layer to be etched is not limited to be positioned atop the pad layer and the fuse structure, and can be disposed above any conductive layer such as above an interconnection layer.

In brief, the method of etching a passivation according to the present invention controls etching selectivity ratio by virtue of adjusting pressure parameter of etching process, and therefore can avoid over-etching. In the above embodiment, a two-step etching process is used. However, the application of the present invention is not limited by two-step etching. For instance, a pressure parameter lower or higher than the pressure parameter of a conventional etching method can be directly set to meet an etching selectivity requirement of a particular etching process. Or a multi-step etching process can be used to control the etching selectivity more accurately.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of etching passivation layer, comprising:
providing a wafer having a passivation layer, the passivation layer comprising an anti-reflection layer and an insulating layer subsequently stacked above the wafer; and
performing an etching process to etch the anti-reflection layer and the insulating layer, wherein an etching selectivity ratio of the anti-reflection layer to the insulating layer of the etching process is greater than 0.029.

2. The method of claim 1, wherein the etching process comprises a plasma etching process.

3. The method of claim 2, wherein the plasma etching process uses a fluoride comprising CF4, SF6, CH3F or NF3.

4. The method of claim 1, wherein the anti-reflection layer comprises a titanium nitride layer, and the insulating layer comprises a silicon oxide layer.

5. The method of claim 1, wherein the wafer further comprises an inter-metal dielectric layer, at least an interconnection layer formed in the inter-metal dielectric layer, a dielectric thin film covering the inter-metal dielectric layer and exposing the interconnection layer, a silicon oxide layer covering the dielectric thin film, a via hole disposed in the silicon oxide layer and exposing the interconnection layer, a barrier layer covering sidewalls of the via hole, and a pad layer disposed on the barrier layer.

6. The method of claim 5, wherein the anti-reflection layer and the insulating layer are stacked on the pad layer.

7. The method of claim 6, wherein the pad layer comprises an aluminum pad layer.

8. The method of claim 1, wherein the etching selectivity ratio of the anti-reflection layer and the insulating layer is achieved by controlling a pressure parameter of the etching process.

9. The method of claim 8, wherein the pressure parameter is substantially 100 mtorr.

10. A method of etching passivation layer, comprising:
providing a wafer having a passivation layer, the passivation layer comprising an anti-reflection layer and an insulating layer subsequently stacked above the wafer; and
performing an etching process to etch the anti-reflection layer and the insulating layer, the etching process comprising a first-step etching performed under a first pressure and a second-step etching performed under a second pressure smaller than the first pressure, wherein an etching selectivity ratio of the anti-reflection layer to the insulating layer of the second-step etching is greater than an etching selectivity ratio of the anti-reflection layer to the insulating layer of the first-step etching.

11. The method of claim 10, wherein the etching process comprises a plasma etching process.

12. The method of claim 11, wherein the plasma etching process uses a fluoride comprising CF4, SF6, CH3F or NF3.

13. The method of claim 10, wherein the anti-reflection layer comprises a titanium nitride layer, and the insulating layer comprises a silicon oxide layer.

14. The method of claim 10, wherein the wafer further comprises an inter-metal dielectric layer, at least an interconnection layer formed in the inter-metal dielectric layer, a dielectric thin film covering the inter-metal dielectric layer and exposing the interconnection layer, a silicon oxide layer covering the dielectric thin film, a via hole disposed in the silicon oxide layer and exposing the interconnection layer, a barrier layer covering sidewalls of the via hole, and a pad layer disposed on the barrier layer.

15. The method of claim 14, wherein the anti-reflection layer and the insulating layer are stacked on the pad layer.

16. The method of claim 15, wherein the pad layer comprises an aluminum pad layer.

17. The method of claim 10, wherein the first pressure is substantially 200 mtorr, and the second pressure is substantially 100 mtorr.

18. A method of etching passivation layer, comprising:
providing a wafer comprising a passivation layer, the passivation layer comprising a titanium nitride layer and a first silicon oxide layer stacked on the wafer, the wafer further comprising a pad layer and a second silicon oxide layer, the titanium nitride layer being disposed on the pad layer and the first silicon oxide layer being disposed on the titanium nitride layer and the second silicon oxide layer; and
performing an etching process to etch the titanium nitride layer and the first silicon oxide layer to expose the pad layer, and to etch the second silicon oxide layer to form a fuse structure, where the etching process comprises a first-step etching performed under a first pressure and a second-step etching performed under a second pressure smaller than the first pressure, wherein an etching selectivity ratio of titanium nitride to silicon oxide of the second-step etching is greater than an etching selectivity ratio of titanium nitride to silicon oxide of the first-step etching.

19. The method of claim 18, wherein the etching process comprises a plasma etching process.

20. The method of claim 19, wherein the plasma etching process uses a fluoride comprising CF4, SF6, CH3F or NF3.

21. The method of claim 18, wherein the pad layer comprises an aluminum pad layer.

22. The method of claim 18, wherein the first pressure is substantially 200 mtorr, and the second pressure is substantially 100 mtorr.
